(19) United States
(12) Patent Application Publication
(10) Pub. No.: US 2011/0029827 A1
(43) Pub. Date: Feb. 3, 2011

(54) METHOD, APPARATUS, AND DESIGN STRUCTURE FOR BUILT-IN SELF-TEST

(75) Inventors: VALERIE H CHICKANOSKY, Essex Junction, VT (US); Kevin W. Gorman, Essex Junction, VT (US); Michael R. Ouellette, Essex Junction, VT (US); Michael A. Ziegerhofer, Essex Junction, VT (US)

Correspondence Address: Wall & Tong, LLP/IBM Burlington, 25 James Way, Eatontown, NJ, 07724, US

(73) Assignee: International Business Machines Corporation, Armonk, NY (US)

(21) Appl. No.: 12/511,739

(22) Filed: Jul. 29, 2009

(51) Int. Cl. G11C 29/04; G06F 11/22

(52) U.S. Cl. 714/718; 714/E11.145; 714/733; 714/744

(57) ABSTRACT

In one embodiment, the invention is a method, apparatus, and design structure for built-in self-test for embedded memory in integrated circuit chips. One embodiment of a method for built-in self-test of an embedded memory includes setting up a plurality of test patterns at a speed of a test clock, where the speed of the test clock is slow enough for a tester to directly communicate with a chip in which the memory is embedded, and where the setting up includes loading a plurality of signal states used to communicate the test patterns to one or more components of a built-in self-test system, applying the test patterns to the embedded memory as a microburst at-speed, capturing output data from the embedded memory at-speed, the output data corresponding to only one of test patterns, and comparing the output data to expected data at the speed of the test clock.

### BACKGROUND OF THE INVENTION

The present invention relates generally to integrated circuits, and relates more specifically a design structure for built-in self-test mechanisms.

A built-in self-test (BIST) mechanism within an integrated circuit (IC) is a function that verifies all or a portion of the internal functionality of the IC. There are many different approaches to architecting memory BIST, each of which has distinct advantages and disadvantages.

For example, one conventional BIST architecture uses a serial path to propagate test data from the BIST engine to the memory when setting up a memory write operation, or from the memory to the BIST engine when collecting data from a memory read operation. The write and read operations are always performed in a parallel or “broadside” manner. Although this approach succeeds in minimizing BIST logic area utilization, it also requires a large number of “overhead cycles” to serially propagate the control and to observe data to and from the memory for each cycle of memory operation. Moreover, since memory units are separated from each other by several serial shift cycles, back-to-back at-speed memory operations are not possible, and effectiveness of at-speed testing is limited. Additionally, the overhead cycles contribute to an increase in test time. This can be mitigated by performing all operations (including the serial shift) “at-speed;” however, this also burdens the chip designer with the task of closing at-speed timing on the serial shift paths (in addition to on the broadside access paths and all of the other functional paths of the chip).

Another conventional approach uses a totally broadside BIST architecture in which all memory inputs and outputs propagate to and from the memory along a wide bus to and from the BIST engine. Although this architecture allows back-to-back “at-speed” memory operations (and, as such, provides good at-speed test coverage for the memory), it also requires higher utilization of the BIST logic at the memory. Further, because the BIST engine and supporting BIST pattern distribution logic, compare logic, encoder logic, and redundancy failing address and repair register (FARR) must be run at-speed when running BIST, a burden is placed on the chip designer to close timing on some BIST logic and on all of the functional logic.

### SUMMARY OF THE INVENTION

In one embodiment, the invention is a method, apparatus, and design structure for built-in self-test for embedded memory in integrated circuit chips. One embodiment of a method for built-in self-test of an embedded memory includes setting up a plurality of test patterns at a speed of a test clock, where the speed of the test clock is slow enough for a tester to directly communicate with a chip in which the memory is embedded, and where the setting up includes loading a plurality of signal states used to communicate the test patterns to one or more components of a built-in self-test system, applying the test patterns to the embedded memory as a microburst at-speed, capturing output data from the embedded memory at-speed, the output data corresponding to only one of test patterns, and comparing the output data to expected data at the speed of the test clock.

### BRIEF DESCRIPTION OF THE DRAWINGS

So that the manner in which the above recited features of the present invention can be understood in detail, a more particular description of the invention may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram illustrating one embodiment of a built-in self-test (BIST) system, according to the present invention;

FIG. 2 is a flow diagram illustrating one embodiment of a method for built-in self-test of embedded memory, according to the present invention;

FIG. 3 is a flow diagram illustrating a first embodiment of a method for applying burst operations to a memory, according to the present invention;

FIG. 4 is a flow diagram illustrating a second embodiment of a method for applying burst operations to a memory, according to the present invention;

FIG. 5 is a high level block diagram of the present built-in self-test method that is implemented using a general purpose computing device; and

FIG. 6 is a flow diagram of a design process used in semiconductor design, manufacture, and/or test.

### DETAILED DESCRIPTION

In one embodiment, the present invention is a method and apparatus for improved built-in self-test for integrated circuit chips. Embodiments of the invention reduce test area overhead of at-speed built-in self-test through two main mechanisms: (1) time-multiplexing of test logic; and (2) an asynchronous interface that allows the test inputs (test patterns) provided to the memory and the test results (output data bits) captured from the memory to be set up and compared at low-speed, but executed within the memory at high-speed. This allows a tester to communicate with a chip and removes the requirement for most of the built-in self-test logic to run fast.

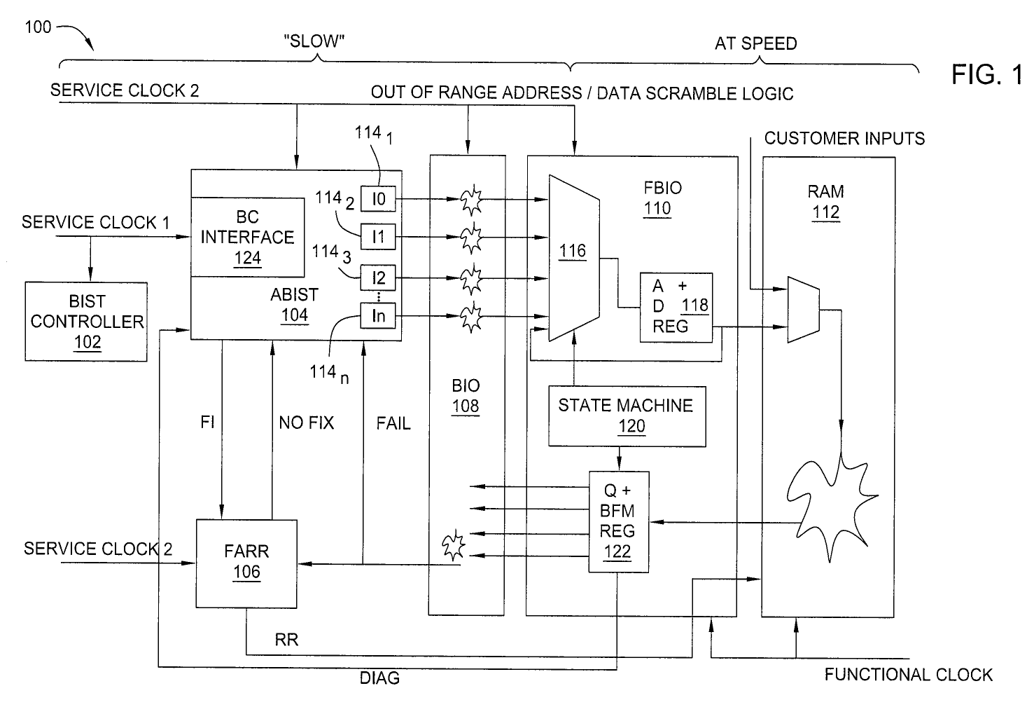

FIG. 1 is a schematic diagram illustrating one embodiment of a built-in self-test (BIST) system 100, according to the present invention. The BIST system 100 may be incorporated, for example, on an integrated circuit (IC) chip. As illustrated, the BIST system 100 is configured for testing a memory 112. Although the memory 112 is illustrated as being a random access memory (RAM), those skilled in the art will appreciate that the BIST system 100 can be configured for testing memory of substantially any type (e.g., read only memory, register file memory, single port memory, dual port memory, content-addressable memory, etc.). Moreover, although the BIST system 100 is illustrated as being configured for the testing of a single memory 112, the BIST system 100 may be configured for testing a plurality of memories.

As illustrated, the BIST system 100 comprises a BIST controller 102, a BIST engine 104 (e.g., an asynchronous BIST or ABIST engine), a comparator/encoder 106, a first BIST collar (BIO) 108, and a second, “fast” BIST collar (FBIO) 110.

The BIST controller 102 schedules and enables BIST operations. The BIST controller 102 is coupled directly to the BIST engine 104, via a BIST controller (BC) interface 124 in the BIST engine 104. The BIST engine 104 is responsible for setting up cycles of memory operation (i.e., a combination of read and/or write operations, hereinafter referred to as “test patterns”) to apply to the memory 112. Within this context, “setting up” a test pattern refers to the act of loading into the registers 114 the specific digital signal states needed to communicate the test patterns to the first BIST collar 108. The test patterns comprise signals designed to enable and diagnose the memory 112. The BIST engine 104 comprises a plurality of registers 114₁-114ₙ (hereinafter collectively referred to as “registers 114”), in which a plurality of test patterns is set up (e.g., one test pattern per register 114). In one embodiment, the BIST engine 104 sets up these test patterns at a “slow” test clock speed, where the test clock speed is slow enough for a tester to directly communicate with the built-in self-test (e.g., in the range of approximately fifty to approximately two hundred fifty megahertz). In one embodiment, the slow clock is slow relative to the at-speed functional clock of the memory, although there may be instances in which the at-speed clock is actually slower than the “slow” clock.

The BIST engine 104 is directly coupled to the first BIST collar 108 and provides the test patterns, via the registers 114, to the first BIST collar 108 at the test clock speed. As described in further detail below, the BIST engine 104 provides the test patterns in groups as “microbursts” to the first BIST collar 108. In one embodiment, a microburst comprises two or more test patterns. Each microburst spans a single memory address or a small subset of the total memory address space. As such, testing of the full memory address space will generally require a plurality of microbursts.

The first BIST collar 108 is also directly coupled to the comparator/encoder 106. As described in further detail below, the first BIST collar 108 receives output data bits from the memory via the second BIST collar 110 (i.e., via an output capture register of the second BIST collar 110) and forwards these output data bits to the comparator/encoder 106 for comparison and/or encoding.

The first BIST collar 108 is directly coupled to the second BIST collar 110, and sets up the test patterns to the second BIST collar 110 at the slow test clock speed. The second BIST collar 110 comprises a multiplexer 116, an address (A&D) register 118, a state machine 120, and an output capture (Q&BFM) register 122. The multiplexer 116 receives the test patterns from the first BIST collar 108 and allows the at-speed capture of the selected test patterns to the address, data and control (A&D) register 118, which is configured to apply the test patterns directly to the memory 112 at-speed. In addition, the address, data and control register 118 returns one of the test patterns to the multiplexer 116 in order to keep the memory running until the next microburst. The output capture register 122 of the second BIST collar 110 is configured for capturing output data bits from one of a set of applied test patterns (i.e., one test pattern per micro-burst) at-speed from the memory 112, and for subsequently providing the output data bits to the first BIST collar 108 at the slow speed. Each group of output data bits represents a portion (1/n) of the word width of the memory 112, where the portion is directly proportional to the number of test patterns (n) in a microburst. In the example shown in FIG. 1, the value of n is four.

The comparator/encoder 106 receives output data bits captured by the output capture register 122 of the second BIST collar 110 from the memory 112, which are provided to the comparator/encoder 106 via the first BIST collar 108. The comparator/encoder 106 compares the output data bits with expected data in order to determine if there is a match. In one embodiment, the expected data is generated by the BIST engine 104 in accordance with methods known to those of skill in the art. The comparator/encoder 106 outputs a signal indicative of the result of the comparison to the BIST engine 104. The output signal from the comparator portion of the comparator/encoder 106 is a fail signal (i.e., the BIST system 100 has encountered a fail), whereas the output signals from the encoder portion of the comparator/encoder 106 represent the failing column address of the fail. The encoder portion will also output a multiple-hit detect signal, for the case where more than one data out bit of the memory 112 has failed. The comparator/encoder 106 has a width equal to approximately 1/n the word width of the memory 112, where n is the number of test patterns contained in a microburst (e.g., if a microburst comprises 4 test patterns, the width of the comparator/encoder 106 is ¼). As described in further detail below, this allows the comparator/encoder logic to be shared across the n test patterns. The comparator/encoder 106 compares and/or encodes 1/n of the data output bits received from the memory 112 during each of the slow clock cycles used by the BIST engine 104 to set up a microburst. Thus, while the BIST engine 104 is setting up the next microburst, the comparator/encoder 106 evaluates the results of the “just-applied” microburst.

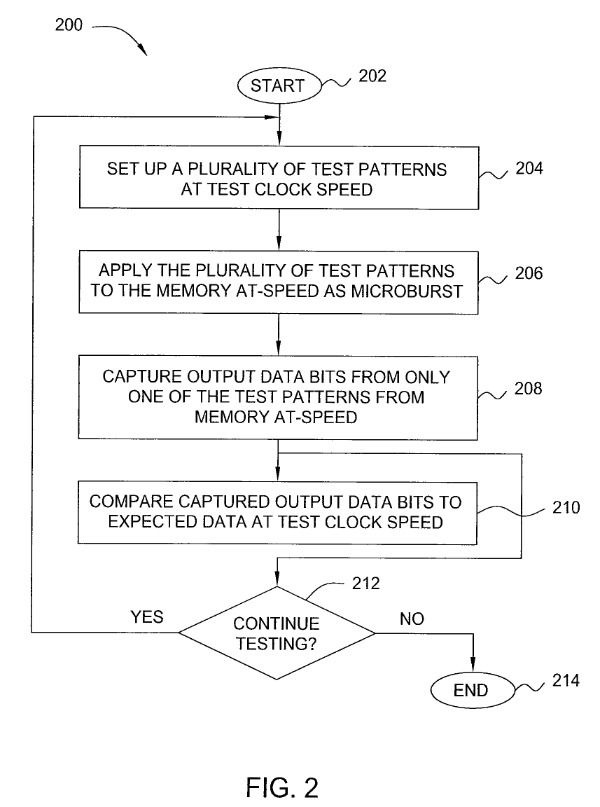

FIG. 2 is a flow diagram illustrating one embodiment of a method 200 for built-in self-test of embedded memory, according to the present invention. The method 200 may be implemented for example, in the BIST system 100 illustrated in FIG. 1. As such, reference is made in the discussion of the method 200 to various elements of the BIST system 100. However, it will be appreciate that the method 200 is not limited to use with the BIST system 100, and that the method 200 may be implemented in BIST systems having alternate configurations.

The method 200 is initialized at step 202 and proceeds to step 204, where the BIST engine performs a setup of a first plurality of test patterns. In one embodiment, the BIST engine performs a setup of four test patterns, though in other embodiments the first plurality of test patterns can total any number of test patterns that is two or greater. In general, a smaller number of test patterns results in less effective testing from an at-speed and noise perspective, as well as a less significant savings in BIST area utilization; however, the smaller the number of test patterns, the smaller the amount of test-time impact. A greater number of test patterns generally results in more effective testing from an at-speed and noise perspective, as well as greater savings in BIST area utilization; however, the greater the number of test patterns, the greater the amount of test-time impact. The first plurality of test patterns is set up using a “slow,” tester-controlled clock. In one embodiment, the “slow” clock runs at any speed that is slower than the memory's at-speed functional clock.

In step 206, the BIST engine applies the first plurality of test patterns, via the first BIST collar and the second BIST collar, as a first “microburst” to the memory, using the memory's at-speed functional clock.

In step 208, the output capture register captures output data bits from only one of the test patterns applied in the microburst in step 206. The output data bits comprise the result of application of the corresponding test pattern to the memory and are captured at-speed.

Having captured the output data bits, the method 200 proceeds simultaneously to steps 210 and 212. In step 210, the comparator/encoder compares the output data bits to expected data, at the test clock speed, in order to determine if there is a memory fail. In one embodiment, the comparator/encoder sends a signal to the BIST engine indicative of the results of the comparison. In one embodiment, the comparator/encoder identifies not just the existence of a fail, but also the specific component(s) within the memory (e.g., data bit(s)) that has failed.

In step 212, the BIST engine determines whether to continue testing (i.e., whether any untested memory space remains). If the BIST engine concludes in step 212 that testing does not need to continue, the method 200 terminates in step 214.

Alternatively, if the BIST engine concludes in step 212 that testing should continue, the method 200 returns to step 204, where the BIST engine sets up a next plurality of test patterns at the test clock speed. While it might appear from the flowchart of FIG. 2 that step 204 occurs after step 210, in actuality, there are no cycles used during the decision step 212. Therefore, if the decision step 212 concludes that testing should continue, the next step 204 (setup of the next microburst) and the present step 210 (comparison of output from present microburst) will actually occur concurrently, during the same “slow clock” setup/compare cycles. However, if decision step 212 concludes that testing should not continue, then present step 210 occurs by itself, and then the testing in accordance with the method 200 completes. Thus, the next microburst of test patterns is set up by the BIST engine while the output data bits from the previously applied microburst are evaluated by the comparator/encoder. In one embodiment, where a microburst comprises n test patterns, 1/n of the output data bits are compared and/or encoded by the comparator/encoder during each of the n test clock cycles required for the BIST engine to set up the next microburst.

Thus, the BIST system of the present invention limits the amount of BIST architecture that must be run at-speed. Specifically, only the memory and the second BIST collar need to be run at-speed, while the remainder of the BIST system (i.e., the BIST engine, the first BIST collar, and the FARR) can be run at a slower speed. This greatly reduces the design time required to close functional timing for a design of an IC chip, which may comprises many hundreds of embedded memories.

Moreover, because the width of the comparator/encoder is only a fraction of the memory word width, the chip area utilized by the BIST logic is greatly reduced. In addition, because the comparing and encoding is performed using the slow clock, the comparing and encoding functions can be powered down, requiring even less chip area.

Additionally, because memory output data is captured at-speed, but compared later during slow clock cycles, a real-time bit fail map for an at-speed memory failure can be generated with the slow clock and captured by the BIST engine. This enables tester clock-controlled at-speed memory diagnostics. That is, fails can be detected by the BIST system during a slow-clock compare sequence, and because the test data (output data bits from the memory) is still in the output capture register at the time of such detection, the location of the specific component(s) within the memory that has failed can be quickly identified.

One risk associated with BIST architectures that test the memory in a series of at-speed burst operations is poor test quality. Specifically, as discussed above, the at-speed bursts are separated by a number of non-operational cycles in which the memory is not accessed. These non-operational cycles are generated as the BIST engine readies data for the next burst and processed data from the last burst. There can be anywhere from one (or a small fraction of one) of these setup operations per one at-speed operation to many hundreds of setup operations per one at-speed operation, depending of the specific BIST architecture.

These non-operational cycles reduce test quality because the memory is inactive and therefore consumes much less power during the set up of the test patterns. During the actual burst portion of the test, however, the memory immediately begins consuming active power, which can result in significantly increased noise and reduced or collapsed power supplies. As such, several cycles of the burst may experience a localized test environment that is much different from the normal operating environment. Since many tests are run under stressful voltage or temperature settings, the noise and power supply issues may result in significant over-testing, which will, in turn, produce poor yield. Testing under less stressful conditions to account for environmental changes at the beginning of each burst can alternatively lead to significant under-testing for memory operations in later bursts (after the power supplies have recovered).

Thus, further embodiments of the present invention modify the state machine 120 illustrated in FIG. 1 to support additional functionalities. These additional functionalities include: (1) the ability to capture output data bits from the memory only during a “valid” portion of the test; and (2) the ability to enter a different state after the valid portion of the test, where the different state keeps the memory active. In one particular embodiment, output data bits are captured only on cycles that are marked as valid by the state machine 120. After the burst operation has completed, the state machine 120 continues to send “dummy” instructions to the memory. The purpose of these dummy instructions is to keep the memory consuming active power (i.e., keep the memory “warmed up”) in between burst operations.

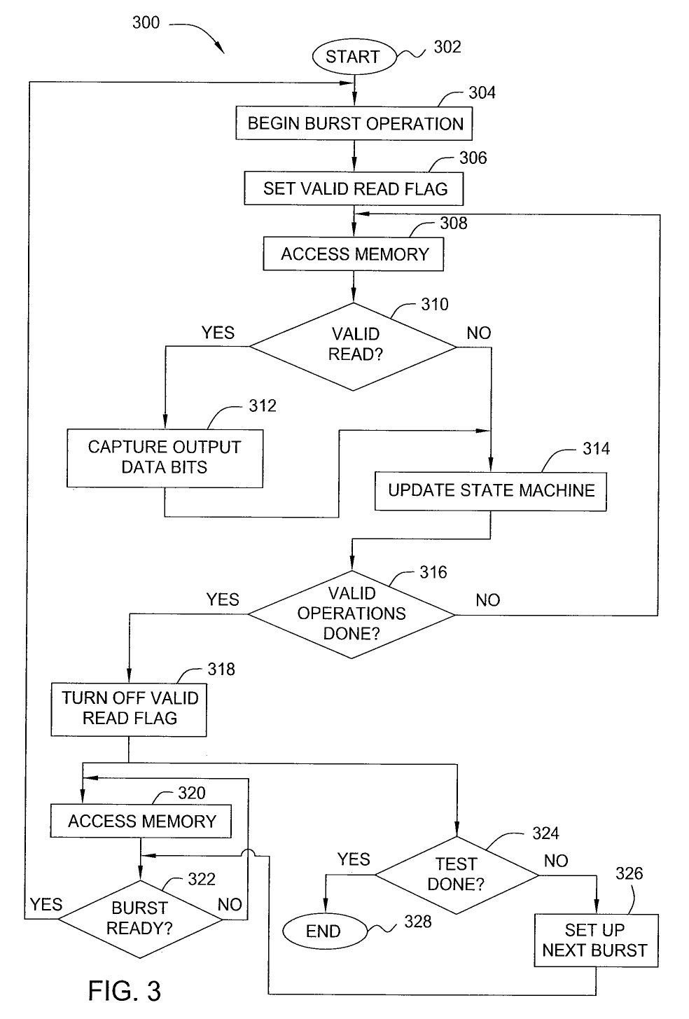

FIG. 3 is a flow diagram illustrating a first embodiment of a method 300 for applying burst operations to a memory, according to the present invention. The method 300 may be implemented, for example, by the BIST system 100 of FIG. 1. As such, reference is made in the discussion of the method 300 to various elements of the BIST system 100. However, it will be appreciate that the method 300 is not limited to use with the BIST system 100, and that the method 300 may be implemented in BIST systems having alternate configurations.

The method 300 is initialized at step 302 and proceeds to step 304, where the BIST system 100 begins a burst operation (i.e., begins accesses to the memory 112). In step 306, the state machine 120 sets a valid read flag, so that read operations performed in accordance with the burst operation are treated as valid (i.e., output data bits will be captured for observation and comparison, as discussed above).

In step 308, the BIST system 100 accesses the memory 112 in accordance with the burst operation. In step 310, the BIST system 100 determines whether the memory access (e.g., read operations) is valid. In one embodiment, this step involves confirming that the valid read flag is set. If the BIST system 100 concludes in step 310 that the memory access is valid, the method 300 proceeds to step 312, where the BIST system captures output data bits from the memory 112, as discussed above. The method 300 then proceeds to step 314, where the state machine 120 updates. Alternatively, if the BIST system 100 concludes in step 310 that the memory access is not valid, the method 300 proceeds directly to step 314.

In step 316, the BIST system 100 determines whether the valid memory accesses have been completed. If the BIST system 100 determines in step 316 that the valid memory accesses have not been completed, the method 300 returns to step 308, and the BIST system 100 continues to access the memory 112.

Alternatively, if the BIST system 100 determines in step 316 that the valid memory accesses have been completed, the method 300 proceeds to step 318, where the state machine 120 turns off or disables the valid read flag. The method 300 then proceeds with two separate operations, which in one embodiment are performed substantially in parallel.

According to the first of these operations, the method 300 proceeds to step 320, where the BIST system 100 accesses the memory 112. In step 322, the BIST system 100 determines whether the next burst is ready to apply. If the BIST system 100 concludes in step 322 that the next burst is not ready, the method 300 returns to step 320, and the BIST system 100 continues to access the memory 112.

Alternatively, if the BIST system 100 concludes in step 322 that the next burst is ready, the method 300 returns to step 304 and proceeds as described above to begin the next burst operation.

According to the second of the two operations, in step 324, the BIST system 100 determines whether testing of the memory 112 is done. If the BIST system 100 concludes in step 324 that the test is done, the method 300 terminates in step 328. Alternatively, if the BIST system 100 concludes in step 324 that the test is not done, the method 300 proceeds to step 326, where the BIST system 100 sets up the next burst for application to the memory 112. The method 300 then proceeds to step 322 and proceeds as described above to begin the next burst operation, once the next burst is ready.

Thus, even once valid operations in accordance with a particular burst are completed, the BIST system 100 continues to access the memory 112, while at the same time the next burst is set up in the background. In other words, the BIST system 100 prepares for the next burst while the memory 112 continues to be operated. In some embodiments, the last operation to the memory is re-sent during this time, so that the memory continues to be accessed during the setup. However, the read data is not captured or processed because the valid read flag is turned off. Thus, the valid read flag controls whether output data bits are captured from the memory 112 and processed. In one embodiment, one or more shadow registers or data hold states are implemented in the BIST system architecture in order to enable this functionality.

Re-executing the last read operation to the memory 112, as discussed above, will generate valid noise similar to normal memory operations. Moreover, there are certain fail mechanisms that respond to repeated reads of a memory cell over a long period of time (so that the next time a valid read of the memory cell is performed, a “continuous-read fail” may be observed). However, a drawback of re-executing the last write operation to the memory is that writing a given memory cell repeatedly may force the memory cell, if weakly written (i.e., defective), into a passing state, thus hiding a true error.

In an alternative embodiment of the present invention, an addition is made to the memory 112 in order to detect weak write fails. In this embodiment, the memory 112 provides a control signal that the BIST system 100 can activate during write operations that occur while the BIST system is setting up test patterns. The control signal allows the bit lines to be activated (which accounts for most of the power consumption when the memory 112 is accessed), but the word line is not activated. This prevents weakly written memory cells from being re-written over time into a passing state, while still producing much of the normal noise profile and power consumption of a standard write operation.

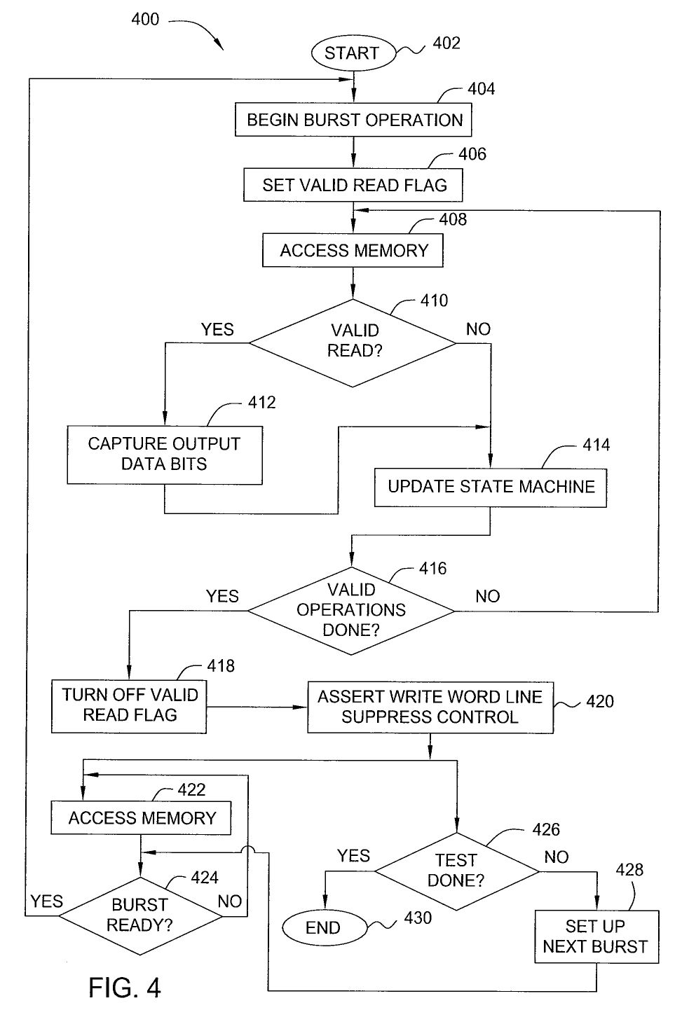

FIG. 4 is a flow diagram illustrating a second embodiment of a method 400 for applying burst operations to a memory, according to the present invention. The method 400 may be implemented, for example, by the BIST system 100 of FIG. 1. As such, reference is made in the discussion of the method 400 to various elements of the BIST system 100. However, it will be appreciate that the method 400 is not limited to use with the BIST system 100, and that the method 400 may be implemented in BIST systems having alternate configurations.

The method 400 is initialized at step 402 and proceeds to step 404, where the BIST system 100 begins a burst operation (i.e., begins accesses to the memory 112). In step 406, the state machine 120 sets a valid read flag, so that read operations performed in accordance with the burst operation are treated as valid (i.e., output data bits will be captured for observation and comparison, as discussed above).

In step 408, the BIST system 100 accesses the memory 112 in accordance with the burst operation. In step 410, the BIST system 100 determines whether the memory access (e.g., read operations) is valid. In one embodiment, this step involves confirming that the valid read flag is set. If the BIST system 100 concludes in step 410 that the memory access is valid, the method 400 proceeds to step 412, where the BIST system captures output data bits from the memory 112, as discussed above. The method 400 then proceeds to step 414, where the state machine 120 updates. Alternatively, if the BIST system 100 concludes in step 410 that the memory access is not valid, the method 400 proceeds directly to step 414.

In step 416, the BIST system 100 determines whether the valid memory accesses have been completed. If the BIST system 100 determines in step 416 that the valid memory accesses have not been completed, the method 400 returns to step 408, and the BIST system 100 continues to access the memory 112.

Alternatively, if the BIST system 100 determines in step 416 that the valid memory accesses have been completed, the method 400 proceeds to step 418, where the state machine 120 turns off or disables the valid read flag. In step 420, the memory 112 asserts write word line suppress control, as discussed above. In particular, the word lines of the cells in the memory 112 are suppressed (not activated), while the bit lines are activated. The method 400 then proceeds with two separate operations, which in one embodiment are performed substantially in parallel.

According to the first of these operations, the method 400 proceeds to step 422, where the BIST system 100 accesses the memory 112. In step 424, the BIST system 100 determines whether the next burst is ready to apply. If the BIST system 100 concludes in step 424 that the next burst is not ready, the method 400 returns to step 422, and the BIST system 100 continues to access the memory 112.

Alternatively, if the BIST system 100 concludes in step 424 that the next burst is ready, the method 400 returns to step 404 and proceeds as described above to begin the next burst operation.

According to the second of the two operations, in step 426, the BIST system 100 determines whether testing of the memory 112 is done. If the BIST system 100 concludes in step 426 that the test is done, the method 400 terminates in step 430. Alternatively, if the BIST system 100 concludes in step 426 that the test is not done, the method 400 proceeds to step 428, where the BIST system 100 sets up the next burst for application to the memory 112. The method 400 then proceeds to step 424 and proceeds as described above to begin the next burst operation, once the next burst is ready.

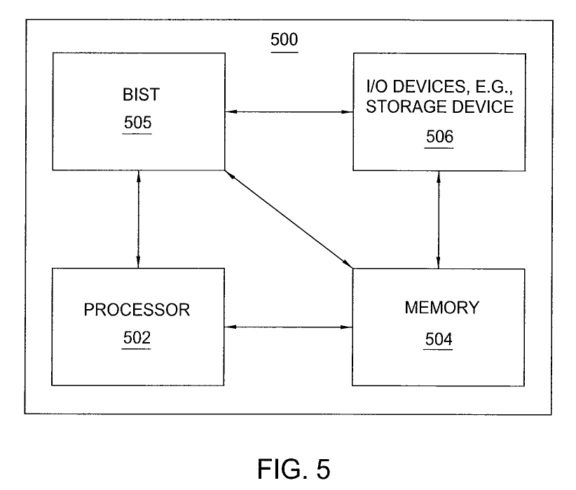

FIG. 5 is a high level block diagram of the present built-in self-test method that is implemented using a general purpose computing device 500. In one embodiment, a general purpose computing device 500 comprises a processor 502, a memory 504, a BIST module 505 and various input/output (I/O) devices 506 such as a display, a keyboard, a mouse, a modem, a microphone, a speaker, a network connection and the like. In one embodiment, at least one I/O device is a storage device (e.g., a disk drive, flash memory, an optical disk drive, a floppy disk drive). It should be understood that the BIST module 505 can be implemented as a physical device or subsystem that is coupled to a processor through a communication channel.

Alternatively, the BIST module 505 can be represented by one or more software applications (or even a combination of software and hardware, e.g., using Application-Specific Integrated Circuits (ASIC)), where the software is loaded from a storage medium (e.g., I/O devices 506) and operated by the processor 502 in the memory 504 of the general purpose computing device 500. Additionally, the software may run in a distributed or partitioned fashion on two or more computing devices similar to the general purpose computing device 500. Thus, in one embodiment, the BIST module 505 for testing embedded memory described herein with reference to the preceding figures can be stored on a computer readable storage medium (e.g., RAM, magnetic or optical drive or diskette, and the like).

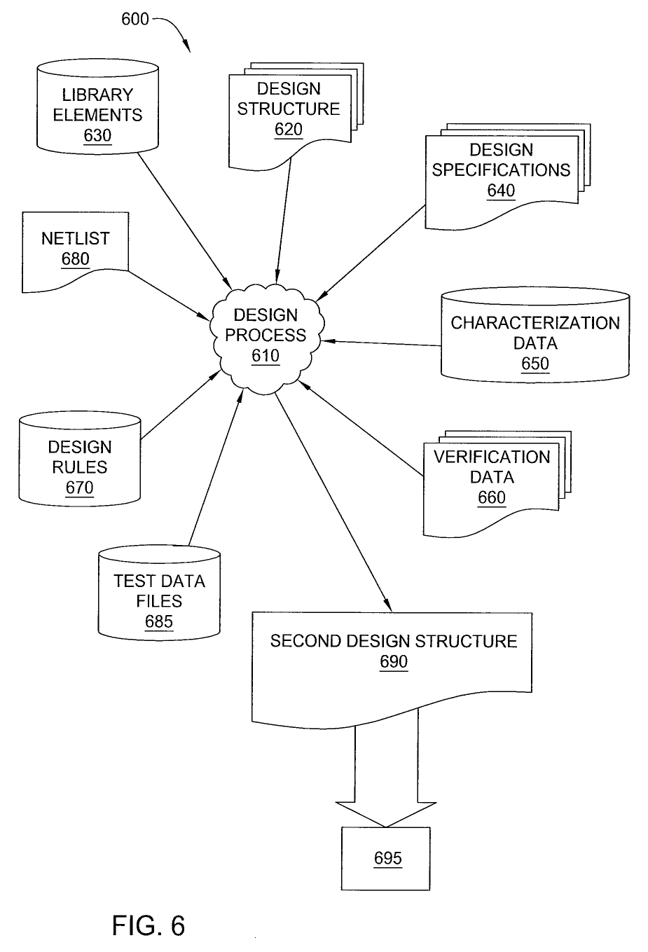

FIG. 6 is a flow diagram of a design process 600 used in semiconductor design, manufacture, and/or test. Specifically, FIG. 6 shows a block diagram of an exemplary design flow 600 used for example, in semiconductor IC logic design, simulation, test, layout, and manufacture. Design flow 600 includes processes, machines, and/or mechanisms for processing design structures or devices to generate logically or otherwise functionally equivalent representations of the design structures and/or devices described above and shown in FIGS. 1-5. The design structures processed and/or generated by design flow 600 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 600 may vary depending on the type of representation being designed. For example, a design flow 600 for building an application specific IC (ASIC) may differ from a design flow 600 for designing a standard component or from a design flow 600 for instantiating the design into a programmable array, for example a programmable gate array (PGA) or a field programmable gate array (FPGA) offered by Altera® Inc. or Xilinx® Inc.

FIG. 6 illustrates multiple such design structures including an input design structure 620 that is preferably processed by a design process 610. Design structure 620 may be a logical simulation design structure generated and processed by design process 610 to produce a logically equivalent functional representation of a hardware device. Design structure 620 may also or alternatively comprise data and/or program instructions that when processed by design process 610, generate a functional representation of the physical structure of a hardware device. Whether representing functional and/or structural design features, design structure 620 may be generated using electronic computer-aided design (ECAD) such as implemented by a core developer/designer. When encoded on a machine-readable data transmission, gate array, or storage medium, design structure 620 may be accessed and processed by one or more hardware and/or software modules within design process 610 to simulate or otherwise functionally represent an electronic component, circuit, electronic or logic module, apparatus, device, or system such as those shown in FIGS. 1-5. As such, design structure 620 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and very high speed integrated circuits HDL (VHDL), and/or higher level design languages such as C or C++.

Design process 610 preferably employs and incorporates hardware and/or software modules for synthesizing, translating, or otherwise processing a design/simulation functional equivalent of the components, circuits, devices, or logic structures shown in FIGS. 1-5 to generate a netlist 680 which may contain design structures such as design structure 620. Netlist 680 may comprise, for example, compiled or otherwise processed data structures representing a list of wires, discrete components, logic gates, control circuits, I/O devices, models, etc. that describes the connections to other elements and circuits in an integrated circuit design. Netlist 680 may be synthesized using an iterative process in which netlist 680 is re-synthesized one or more times depending on design specifications and parameters for the device. As with other design structure types described herein, netlist 680 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 610 may include hardware and software modules for processing a variety of input data structure types including netlist 680. Such data structure types may reside, for example, within library elements 630 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 640, characterization data 650, verification data 660, design rules 670, and test data files 685 which may include input test patterns, output test results, and other testing information. Design process 610 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 610 without deviating from the scope and spirit of the invention. Design process 610 may also include modules for performing standard circuit design processes such as timing analysis, verification, design rule checking, place and route operations, etc.

Design process 610 employs and incorporates logic and physical design tools such as HDL compilers and simulation model build tools to process design structure 620 together with some or all of the depicted supporting data structures along with any additional mechanical design or data (if applicable), to generate a second design structure 690. Second design structure 690 resides on a storage medium or programmable gate array in a data format used for the exchange of data of mechanical devices and structures (e.g. information stored in an initial graphics exchange specification (IGES), drawing exchange format (DXF), Parasolid XT, JT, DRG, or any other suitable format for storing or rendering such mechanical design structures). Similar to design structure 620, second design structure 690 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-5. In one embodiment, second design structure 690 may comprise a compiled, executable HDL simulation model that functionally simulates the devices shown in FIGS. 1-5.

Second design structure 690 may also employ a data format used for the exchange of layout data of integrated circuits and/or symbolic data format (e.g. information stored in a GDSII (GDS2), GL1, OASIS, map files, or any other suitable format for storing such design data structures). Second design structure 690 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-5. Second design structure 690 may then proceed to a stage 695 where, for example, second design structure 690: proceeds to tape-out, is released to manufacturing, is released to a mask house, is sent to another design house, is sent back to the customer, or the like.

It should be noted that although not explicitly specified, one or more steps of the methods described herein may include a storing, displaying and/or outputting step as required for a particular application. In other words, any data, records, fields, and/or intermediate results discussed in the methods can be stored, displayed, and/or outputted to another device as required for a particular application. Furthermore, steps or blocks in the accompanying Figures that recite a determining operation or involve a decision, do not necessarily require that both branches of the determining operation be practiced. In other words, one of the branches of the determining operation can be deemed as an optional step.

While the foregoing is directed to embodiments of the present invention, other and further embodiments of the invention may be devised without departing from the basic scope thereof. Various embodiments presented herein, or portions thereof, may be combined to create further embodiments. Furthermore, terms such as top, side, bottom, front, back, and the like are relative or positional terms and are used with respect to the exemplary embodiments illustrated in the figures, and as such these terms may be interchangeable.

What is claimed is:

1. A method for built-in self-test of an embedded memory, comprising:
setting up a plurality of test patterns at a speed of a test clock, where the speed of the test clock is slow enough for a tester to directly communicate with a chip in which the embedded memory is embedded, and where the setting up comprises loading a plurality of signal states used to communicate the plurality of test patterns to one or more components of a built-in self-test system;
applying the plurality of test patterns to the embedded memory as a microburst at-speed;
capturing output data from the embedded memory at-speed, the output data corresponding to only one of the plurality of test patterns; and
comparing the output data to expected data at the speed of the test clock.

2. The method of claim 1, wherein the comparing is performed while a next plurality of test patterns is being set up.

3. The method of claim 1, further comprising:
outputting a signal indicative of a result of the comparing.

4. The method of claim 3, wherein the signal identifies at least one of: an existence of a memory fail or a specific component associated with the memory fail.

5. The method of claim 1, wherein the speed of the test clock is in a range of approximately fifty to approximately two hundred fifty megahertz.

6. The method of claim 1, wherein the microburst spans a single memory address or a subset of a total address space of the embedded memory.

7. The method of claim 1, wherein the plurality of test patterns includes at least one of: a memory read operation or a memory write operation.

8. The method of claim 1, wherein said output data represents a portion of a word width of the embedded memory.

9. The method of claim 8, wherein the portion is directly proportional to a number of said plurality of test patterns.

10. The method of claim 1, wherein the embedded memory is one of: a random access memory, a read only memory, a register file memory, a single port memory, a dual port memory, or a content-addressable memory.

11. The method of claim 1, wherein the speed of the test clock is slower than an at-speed functional clock of the embedded memory.

12. The method of claim 1, further comprising:
applying one or more dummy instructions to the embedded memory after the output data is captured, and before a next plurality of test patterns is applied.

13. The method of claim 12, wherein no output data is captured in response to the applying of the one or more dummy instructions.

14. The method of claim 12, wherein the one or more dummy instructions is applied in response to an activation of a flag.

15. The method of claim 12, further comprising:
activating a control signal after applying the one or more dummy instructions, where the control signal suppresses one or more word lines in one or more cells of the embedded memory.

16. A computer readable storage medium containing an executable program for built-in self-test of an embedded memory, where the program performs the steps of:
setting up a plurality of test patterns at a speed of a test clock, where the speed of the test clock is slow enough for a tester to directly communicate with a chip in which the embedded memory is embedded, and where the setting up comprises loading a plurality of signal states used to communicate the plurality of test patterns to one or more components of a built-in self-test system;
applying the plurality of test patterns to the embedded memory as a microburst at-speed;
capturing output data from the embedded memory at-speed, the output data corresponding to only one of the plurality of test patterns; and
comparing the output data to expected data at the speed of the test clock.

17. A built-in self-test (BIST) system for testing an embedded memory, the system comprising:
a BIST collar for applying the plurality of test patterns to the embedded memory;
a BIST engine for setting up a plurality of test patterns, where the setting up comprises loading a plurality of signal states used to communicate the plurality of test patterns to the BIST collar;
an output capture register for capturing output data from the embedded memory, the output data corresponding to only one of the plurality of test patterns; and
a comparator/encoder for comparing the output data to expected data, wherein the comparator/encoder has a width that is a fraction of a word width of the embedded memory.

18. The BIST system of claim 17, wherein the BIST engine is configured to set up the plurality of test patterns at a speed of a test clock, where the speed of the test clock speed is slow enough for a tester to directly communicate with a chip in which the memory is embedded.

19. The BIST system of claim 17, wherein the BIST collar comprises:
a first BIST collar directly coupled to the BIST engine for receiving the plurality of test patterns at a speed of a test clock, where the speed of the test clock speed is slower than an at-speed functional clock of the embedded memory; and
a second BIST collar directly coupled to the first BIST collar for receiving the plurality of test patterns at the test-clock speed from the first BIST collar, the second BIST collar further being directly coupled to the embedded memory and configured for applying the plurality of test patterns to the embedded memory at-speed as a microburst.

20. The BIST system of claim 19, wherein the second BIST collar comprises:
a multiplexer for receiving the microburst from the first BIST collar; and
an address register to which the multiplexer shifts the microburst, the address register being configured to apply the plurality of test patterns in the microburst directly to the embedded memory, the address register being further configured to return one of the plurality of test patterns to the multiplexer.

21. The BIST system of claim 17, wherein the comparator/encoder is configured to perform said comparing at the speed of a test clock, where the speed of the test clock speed is slow enough for a tester to directly communicate with a chip in which the memory is embedded.

22. The BIST system of claim 17, wherein the fraction is 1/n, n being a number of the plurality of test cycles.

23. The BIST system of claim 17, further comprising:
a BIST controller for scheduling and enabling BIST operations.

24. The BIST system of claim 17, wherein the comparator/encoder is further configured to output a signal indicative of a result of the comparing to the BIST engine, wherein the signal identifies at least one of: an existence of a memory fail or a specific component associated with the memory fail.

25. A design structure tangibly embodied in a machine readable medium for designing, manufacturing, or testing an integrated circuit, the design structure comprising:
a built-in self-test (BIST) engine for setting up a plurality of test patterns for testing the integrated circuit, where the setting up comprises loading a plurality of signal states used to communicate the plurality of test patterns to a BIST collar;
the BIST collar for applying the plurality of test patterns to an embedded memory of the integrated circuit;
an output capture register for capturing output data from the embedded memory, the output data corresponding to only one of the plurality of test patterns; and
a comparator/encoder for comparing the output data to expected data, wherein the comparator/encoder has a width that is a fraction of a word width of the embedded memory.
